(19) United States
(12) Patent Application Publication
(10) Pub. No.: US 2014/0006886 A1
(43) Pub. Date: Jan. 2, 2014

(54) MEMORY AND METHOD FOR TESTING THE SAME

(71) Applicant: SK HYNIX INC., Gyeonggi-do (KR)

(72) Inventor: Choung-Ki SONG, Gyeonggi-do (KR)

(73) Assignee: SK hynix Inc., Gyeonggi-do (KR)

(21) Appl. No.: 13/844,946

(22) Filed: Mar. 16, 2013

(30) Foreign Application Priority Data
Jun. 28, 2012 (KR) 10-2012-0069690

(51) Int. Cl. G11C 29/14

(52) U.S. Cl. CPC G11C 29/14
USPC 714/718

(57) ABSTRACT

A memory includes a bank including a plurality of memory cells a command decoder configured to operate in synchronization with a clock signal and activate at least one of a plurality of commands including an active command, a write command, a calibration command, and an MRS command in response to a plurality of command signals, a test decoder configured to set the memory as a test mode in response to a plurality of address signals and the MRS command, and a test controller configured to activate at least one internal test command for test operating the bank at a time point that is decided based on counting information obtained by counting a test clock signal having a higher frequency than the clock signal, when the memory is set in the test mode.

### CROSS-REFERENCE TO RELATED APPLICATIONS

The present application claims priority of Korean Patent Application No. 10-2012-0069690, filed on Jun. 28, 2012, which is incorporated herein by reference in its entirety.

### BACKGROUND

1. Field

Exemplary embodiments of the present invention relate to a memory and a method for testing the same, and more particularly, to a memory test method capable of reducing a test time of a memory while using a test device having a low clock frequency.

2. Description of the Related Art

A memory passes through various tests, in order to check whether or not the memory normally operates after the memory is fabricated. In general, since the memory receives a clock signal and operates in synchronization with the received clock signal, the test device inputs the clock signal to the memory and inputs and outputs test data, while a test of the memory is performed. The memory test may include a test for determining whether a cell normally operates or not, a test for checking a coupling effect between adjacent metal lines, and a test for checking a margin between signals having temporal characteristics. For reference, a time required for performing the test of the memory may be a significant factor in a fabrication cost of the memory. Therefore, as the time required for performing the test of the memory increases, the fabrication cost of the memory may also increase.

Meanwhile, the test device for performing a test of the memory internally generates a clock signal, a command signal, and data for the test, inputs the generated signals and data to the memory, receives data outputted from the memory, and analyzes whether the memory normally operates or not. Since a synchronous memory performs all operations in synchronization with a clock signal inputted from outside, the operation speed of the memory is decided according to the frequency of the clock signal inputted from outside. Therefore, a time required for performing the test of the memory depends on the frequency of the clock signal applied to the memory from the test device.

With the increase in operation speed of the memory, the memory has used a high-frequency clock signal. However, some test devices may have some limits to the frequency of a clock signal which is internally generated therefrom. In this case, when the test of the memory is performed, the memory must be operated in synchronization with a clock signal generated by a test device having a relatively low frequency. Therefore, the time required for testing the memory may increase undesirably.

### SUMMARY

Various embodiments are directed to a memory and a method for testing the same, which is capable of reducing a test time by internally generating a clock signal having a high frequency, even though a test device is used to perform a test when the memory is tested.

Also, various embodiments are directed to a memory and a test for testing the same, which is capable of testing various operations using a clock signal generated inside the memory.

In an embodiment, a memory includes a bank including a plurality of memory cells, a command decoder configured to operate in synchronization with a clock signal and activate at least one of a plurality of commands including an active command, a write command, a calibration command, and an MRS command in response to a plurality of command signals, a test decoder configured to set the memory as a test mode in response to a plurality of address signals and the MRS command, and a test controller configured to activate at least one internal test command for test operating the bank at a time point that is decided based on counting information obtained by counting a test clock signal having a higher frequency than the clock signal, when the memory is set in the test mode.

In another embodiment, a memory includes a bank including a plurality of memory cells, a command decoder configured to operate in synchronization with a clock signal and activate at least one of a plurality of commands including a write command and an MRS command in response to a plurality of command signals, a test decoder configured to set the memory as a test mode in response to a plurality of address signals the MRS command, and a test controller configured to activate a test precharge command for precharging the bank at a time point that is decided based on counting information obtained by counting a test clock signal having a higher frequency than the clock signal after the write command is activated, when the memory is set in the test mode.

In another embodiment, a memory includes a bank including a plurality of memory cells, a command decoder configured to operate in synchronization with a clock signal and activate at least one of a plurality of commands including an active command and an MRS command in response to a plurality of command signals, a test decoder configured to set the memory as a test mode in response to a plurality of address signals and the MRS command, and a test controller configured to activate a test write command for writing data into the bank and a test precharge command for precharging the bank at a time point that is decided based on counting information obtained by counting a test clock signal having a higher frequency than the clock signal when the memory is decided in the test mode.

In another embodiment, a memory includes a bank including a plurality of memory cells, a command decoder configured to operate in synchronization with a clock signal and activate at least one of a plurality of commands including an active command, a write command, a calibration command, and an MRS command in response to a plurality of command signals a test decoder configured to set the memory as one of first to third test modes in response to a plurality of address signals and the MRS command, and a test controller configured to activate a test active command for activating the bank and a test precharge command for precharging the bank at a time point that is decided based on counting information obtained by counting a test clock signal having a higher frequency than the clock signal when the first test mode is set, activate the test precharge command at a time point that is decided based on the counting information after the write command is activated when the second test mode is set, and activate a test write command for writing data into the bank and the test precharge command at a time point that is decided based on the counting information when the third test mode is set.

In another embodiment, there is provided a method for testing a memory which includes a bank having a plurality of memory cells. The method includes setting one of first to third test modes in response to a plurality of address signals when a combination of a plurality of command signals corresponds to an MRS signal, decoding the plurality of command signals in synchronization with a clock signal and activating at least one of a plurality of commands including an active command, a write command, and a calibration command, and activating a test active command for activating the bank and a test precharge command for precharging the bank at a time point that is decided based on counting information obtained by counting a test clock signal having a higher frequency than the clock signal when the first test mode is set, activating the test precharge command at a time point that is decided based on the counting information after the write command is activated when the second test mode is set, and activating a test write command for writing data into the bank and the test precharge command at a time point that is decided based on the counting information when the third test mode is set.

In another embodiment, a memory includes a bank including a plurality of memory cells, a command decoder configured to operate in synchronization with a clock signal and activate at least one of a plurality of commands for an operation of the memory in response to a plurality of command signals, a test decoder configured to set the memory as a test mode in response to a plurality of address signals when a command for setting the test mode among the plurality of commands is activated, and generate test information for a test operation of the bank, and a test controller configured to activate at least one of a plurality of test commands for the test operation of the bank in response to the test information and counting information obtained by counting a test clock signal having a higher frequency than the clock signal when the test mode is set.

### BRIEF DESCRIPTION OF THE DRAWINGS

FIG. 1 is a diagram of a memory in accordance with an exemplary embodiment of the present invention.

FIG. 2 is a diagram of a clock generation control unit in accordance with the exemplary embodiment of the present invention.

FIG. 3 is a diagram of a test clock generation unit in accordance with the exemplary embodiment of the present invention.

FIGS. 4A and 4B are diagrams of a signal generation unit in accordance with the exemplary embodiment of the present invention.

FIG. 5 is a flow chart for explaining a method for testing the memory in accordance with the exemplary embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

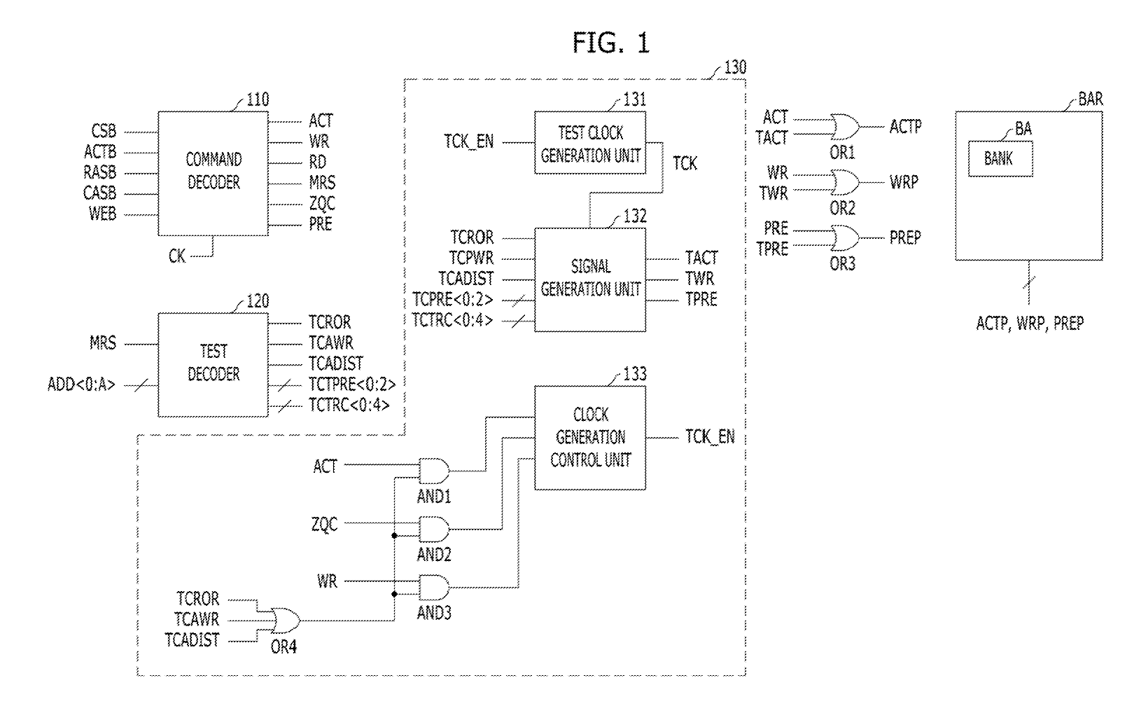

FIG. 1 is a diagram of a memory in accordance with an exemplary embodiment of the present invention.

Referring to FIG. 1, the memory includes a bank BA, a command decoder 110, a test decoder 120, and a test controller 130. The bank BA includes a plurality of memory cells. The command decoder 110 is configured to operate in synchronization with a clock signal CK and activate one or more of a plurality of commands including an active command ACT, a write command WR, a calibration command ZQC, an MRS command MRS, a read command RD, and a precharge command PRE in response to a plurality of command signals CSB, ACTB, RASB, CASB, and WEB. The test decoder 120 is configured to set one test mode among first to third test modes in response to a plurality of address signals ADD<0:A>, when the MRS command MRS is activated. The test controller 130 is configured to activate a test active command TACT for activating the bank BA and a test precharge command TPRE for precharging the bank BA at a time point that is decided based on counting information CNT<0:4> obtained by counting a test clock signal TCK having a higher frequency than the clock signal CK when the first test mode is set, activate the test precharge command TPRE at a time point that is decided based on the counting information CNT<0:4> after the write command WR is activated when the second test mode is set, and activate the test precharge command TPRE and a test write command TWR for writing data into the bank BA at a time point that is decided based on the counting information CNT<0:4> when the third test mode is set.

The plurality of command signals include an active signal ACTB, a chip select signal CSB, a row address strobe signal RASB, a column address strobe signal CASB, and a write enable signal WEB.

Referring to FIG. 1, the memory will be described.

The memory in accordance with the exemplary embodiment of the present invention operates in a test mode or operates in an operation mode which is not the test mode (hereafter, referred to as a normal mode). When the memory operates in the normal mode, the memory operates in synchronization with the clock signal CK applied from outside, and when the memory operates in the test mode, the memory operates in synchronization with a test clock signal TCK which is internally generated therefrom.

The command decoder 110 is configured to generate the plurality of commands ACT, WR, ZQC, MRS, RD, and PRE in synchronization with the clock signal CK, receive the plurality of command signals CSB, ACTB, RASB, CASB, and WEB, and activate a command corresponding to a combination of the received command signals CSB, ACTB, RASB, CASB, and WEB, among the plurality of commands ACT, WR, ZQC, MRS, RD, and PRE. The active command ACT is a command for activating, in other words, enabling the bank BA, the write command WR is a command for writing data into the bank, and the calibration command ZQC is a command for generating an impedance code which is changed depending on process, voltage, and temperature (PVT) conditions such that a data output circuit optimizes a termination impedance value. Furthermore, the MRS command MRS is a command for setting operation environments and conditions of the memory through settings of a mode register set (MRS), the read command RD is a command for reading data of the bank BA, and the precharge command PRE is a command for precharging, in other words, the bank.

The test decoder 120 is configured to generate test time information TCPRE<0:2> and TCTRC<0:4> required for operating in the test mode, when the memory is set in the test mode. More specifically, the test decoder 120 sets the memory in any one of the first to third test modes in response to the MRS command MRS and an address ADD<0:A> and generate the test time information TCPRE<0:2> and TCTRC<0:4> required for the respective modes, when the command decoder 110 activates the MRS command MRS in response to a combination of the plurality of command signals CSB, ACTB, RASB, CASB, and WEB. The test decoder 120 generates first to third test mode signals TCROR, TCAWR, and TCADIST indicating in which mode the memory is set among the first to third test modes. When the memory is set in the first test mode, the first test mode signal TCROR is activated, when the memory is set in the second test mode, the second test mode signal TCAWR is activated, and when the memory is set in the third test mode, the third test mode signal TCADIST is activated.

The first to third test modes are test modes for performing different operation of the memory. The first test mode is a test mode in which an operation to activate the bank BA and an operation to precharge the bank BA are successively performed during a period set by a command. When the memory is set to operate in the first test mode, the memory activates and precharges the bank BA at a predetermined interval during a period from a time point when the active command ACT is activated to a time point when the calibration command ZQC is activated.

The second test mode is a test mode in which the precharge operation of the bank BA is performed in a predetermined time after the write command WR is applied. When the memory is set to operate in the second test mode, the memory precharges the bank BA without the precharge command PRE in a predetermined time after the write command WR is activated.

The third test mode is a test mode in which the memory writes data into the bank BA in a predetermined time after the active command ACT is applied, and precharges the bank BA after a predetermined time passes. When the memory is set to operate in the third test mode, the memory writes data into the bank BA without the write command WR in a predetermined time after the active command ACT is activated, and precharges the bank BA without the precharge command PRE after a predetermined time passes.

Meanwhile, when the memory operates in the test mode, the test controller 130 generates test commands TACT, TWR, and TPRE in a state in which the test mode is set, in order to perform one operation among the active operation of the bank BA, the write operation of the bank BA, and the precharge operation of the bank BA, even though the plurality of commands ACT, WR, ZQC, MRS, RD, and PRE are not activated. Here, time points at which the test commands TACT, TWR, and TPRE are activated may be decided by the test time information TCPRE<0:2> and TCTRC<0:4> and the counting information CNT<0:4> obtained by counting the test clock signal TCK. At this time, the values of the test time information TCPRE<0:2> and TCTRC<0:4> may differ depending on a combination of the address signals ADD<0:A>.

The test controller 130 generates the plurality of test commands TACT, TWR, and TPRE in synchronization with the test clock signal TCK having a higher frequency than the clock signal CK, in order to control the operation of the memory when the memory is set in one test mode among the first to third test modes.

For this operation, the test controller 130 includes a test clock generation unit 131, a signal generation unit 132, and a clock generation control unit 133. The test clock generation unit 131 is configured to generate the test clock signal TCK. The signal generation unit 132 is configured to alternately activate the test active command TACT and the test precharge command TPRE in response to the counting information CNT<0:4> in a state where the memory is set in the first test mode, activate the test precharge command TPRE at a time point that is decided based on the counting information CNT<0:4> and the first test time information TCPRE<0:2> after the write command WR is activated in a state where the memory is set in the second test mode, and activate the test write command TWR at a time point that is decided based on the counting information CNT<0:4> and the first test time information TCPRE<0:2> and activate the precharge signal PRE at a time point that is decided based on the counting information CNT<0:4> and the second test time information TCTRC<0:4>, after the activate command ACT is activated in a state where the memory is set to the third test mode. The clock generation control unit 133 is configured to enable the test clock generation unit 131 in response to the active command ACT and disable the test clock generation unit 131 in response to the calibration command ZQC in a state where the memory is set in the first test mode, enable the test clock generation unit 131 in response to the write command WR and disable the test clock generation unit 131 in response to the test precharge command TPRE in a state where the memory is set in the second test mode, and enable the test clock generation unit 131 in response to the write command WR and disable the test clock generation unit 131 in response to the test precharge command TPRE in a state where the memory is set in the third test mode.

The operation of the test controller 130 will be described in more detail. The test clock generation unit 131 generates the test clock signal TCK during a period in which the test clock generation unit 131 is enabled, when the memory is set in the test mode. In order to reduce the test time, the test clock signal TCK has a higher frequency than the clock signal CK which is generated by a test device and inputted to the memory.

The clock generation control unit 133 is configured to generate a test clock enable signal TCK_EN to enable or disable the test clock generation unit 131 in one of the first to third test modes. The clock generation control unit 133 activates the test clock enable signal TCK_EN in response to the active command ACT and deactivates the test clock enable signal TCK_TK in response to the calibration command ZQC, in the first test mode. Furthermore, the clock generation control unit 133 activates the test clock enable signal TCK_EN in response to the write command WR and deactivates the test clock enable signal TCK_EN in response to the test precharge command TPRE, in the second test mode. Furthermore, the clock generation control unit 133 activates the test clock enable signal TCK_EN in response to the active command ACT, and deactivates the test clock enable signal TCK_EN in response to the test precharge command TPRE, in the third test mode.

For reference, the activate command ACT, the calibration command ZQC, and the write command WR are transmitted to the clock generation control unit 133, only when one or more test mode signals among the first to third test mode signals TCROR, TCAWR, and TCADIST are activated by an OR gate OR4 and a plurality of AND gates AND1 to AND3 illustrated in FIG. 1.

The test clock generation unit 131 is enabled during a period in which the test clock enable signal TCK_EN is activated, and generates the test clock signal TCK. The test clock generation unit 131 is an oscillator including a plurality of unit delays, for example, inverters, and a period in which the test clock TCK is toggled may correspond to the sum of delay values of the plurality of unit delays. In addition, the test clock generation unit 131 may generate the test clock signal TCK by dividing the frequency of the input clock signal CK.

The signal generation unit 132 is configured to activate the test commands TACT, TWR, and TPRE at a proper time point according to the counting information CNT<0:4> obtained by counting the test clock signal TCK and the test mode set by the test time information TCPRE<0:2> and TCTRC<0:4>. The signal generation unit 132 activates the test active command TACT when the counting information CNT<0:4> has a predetermined value and activates the test precharge command TPRE when some bits CNT<0:2> of the counting information CNT<0:4> correspond to the first test time information TCPRE<0:2>, in the first test mode. Furthermore, the signal generation unit 132 activates the test precharge command TPRE when the bits CNT<0:2> of the counting information CNT<0:4> correspond to the first test time information TCPRE<0:2> in the second test mode. Furthermore, the signal generation unit 132 activates the test write command TWR when the bits CNT<0:2> of the counting information CNT<0:4> correspond to the first test time information TCPRE<0:2> and activates the test precharge command TPRE when the counting information CNT<0:4> corresponds to the second test time information TCTRC<0:4>, in the third test mode.

Here, when two pieces of information correspond to each other, it may mean that the corresponding bits of the two pieces of information have the same values. For example, when the bits CNT<0:2> of the counting information CNT<0:4> correspond to the first test time information TCPRE<0:2> in the third test mode, it may indicate that the respective bits CNT<0>, CNT<1>, and CNT<2> are equal to the respective bits TCPRE<0>, TCPRE<1>, and TCPRE<2>. Furthermore, when the counting information CNT<0:4> corresponds to the second test time information TCTRC<0:4>, it may indicate that the respective bits CNT<0>, CNT<1>, CNT<2>, CNT<3>, and CNT<4> are equal to the respective bits TCPRE<0>, TCPRE<1>, TCPRE<2>, TCPRE<3>, and TCPRE<4>.

The above-described configuration is only an example indicating a condition in which the test commands TACT, TWR, and TPRE are activated, and this may differ depending on design. The signal generation unit 132 may activate one of the test commands TACT, TWR, and TPRE when the counting information CNT<0:4> has a predetermined value or when the counting information CNT<0:4> corresponds to one of the test time information TCPRE<0:2> and the TCTRC<0:4>. The numbers of bits of information CNT<0:4>, TCPRE<0:2>, and TCTRC<0:4> may differ depending on design.

When one of the test commands TACT, TWR, and TPRE or the commands ACT, WR, and PRE is activated, pulse signals ACTP, WRP, and PREP for controlling the operation of the bank BA are transmitted to a bank region BAR. For this operation, three OR gates OR2 to OR4 are used. The active pulse signal ACTP is activated in response to the test active command TACT or the active command ACT, the write pulse signal WRP is activated in response to the test write command TWR or the write command WR, and the precharge pulse signal PREP is activated in response to the test precharge command TPRE or the precharge command PRE. The bank region BAR includes a peri-circuit (not illustrated in FIG. 1) configured to control the operation of the bank BA in response to the pulse signals ACTP, WRP, and PREP. The peri-circuit of the bank region BAR activates the bank BA, in other words, enables a word line included in the bank BA when the active pulse signal ACTP is activated, writes input data into memory cells included in the bank BA when the write pulse signal WRP is activated, and precharges the bank BA, in other words, a word line or bit line of the bank BA when the precharge pulse signal PREP is activated.

The memory in accordance with the exemplary embodiment of the present invention performs a test operation by receiving a command signal, a clock signal CLK, data, and an address ADD<0:A> from an external test device or an external memory controller. At this time, the memory internally generates a test clock signal TCK having a higher frequency than the clock signal CK inputted from outside, thereby reducing the test time. Among the above-described signals, the plurality of commands ACT, WR, RD, MRS, ZQC, and PRE are generated in synchronization with the clock signal CK, and the plurality of test commands TACT, TWR, and TPRE are generated in synchronization with the test clock signal TCK.

Meanwhile, FIG. 1 illustrates an example in which the memory supports all of the first to third test modes. However, the memory does not need to support all of the first to third test modes, but may be designed to support one or more of the first to third test modes. For example, the memory may be designed to support one test mode of the first to third test modes or support two or more test modes. When the memory supports a part of the first to third test modes, an operation for a test mode other than the test modes supported by the memory does not need to be performed among the above-described operations.

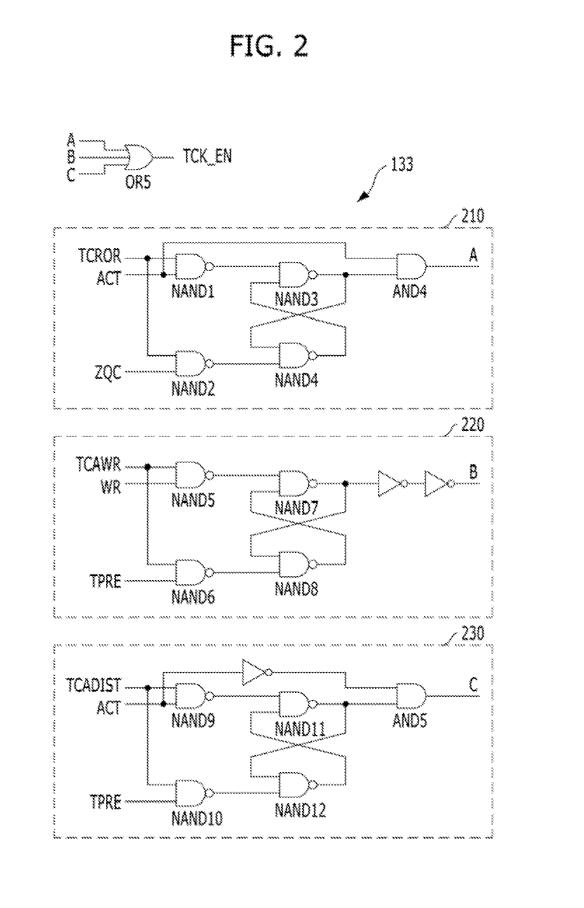

FIG. 2 is a diagram of the clock generation control unit 133 in accordance with the exemplary embodiment of the present invention.

Referring to FIG. 2, the clock generation control unit 133 includes a first control unit 210, a second control unit 220, and a third control unit 230, and an OR gate OR5. The first control unit 210 is configured to control the test clock generation unit 131 when the memory is set in the first test mode. The second control unit 220 is configured to control the test clock generation unit 131 when the memory is set in the second test mode. The third control unit 230 is configured to control the test clock generation unit 131 when the memory is set in the third test mode. The OR gate OR5 is configured to combine outputs A, B, and C of the first to third control units and generate the clock generation enable signal TCK_EN. The first control unit 210 includes a plurality of NAND gates NAND1 to NAND4 and an AND gate AND4, the second control unit 220 includes a plurality of NAND gates NAND5 to NAND8, and the third control unit 230 includes a plurality of NAND gates NAND9 to NAND12 and an AND gate AND5. For reference, ACTT represents a signal which is transmitted by passing the active command ACT through the AND gate AND1 when the memory is set in one of the first to third test modes, ZQCT represents a signal which is transmitted by passing the calibration command ZQCT through the AND gate AND2 when the memory is set in one of the first to third test modes, and WRT represents a signal which is transmitted by passing the write command WR through the AND gate AND3 when the memory is set in one of the first to third test modes.

Referring to FIG. 2, the operation of the clock generation control unit 133 will be described.

The first to third test mode signals TCROR, TCAWR, and TCADIST are deactivated in a state in where the memory is not set in the test mode. Since all of the first to third test mode signals TCROR, TCAWR, and TCADIST are low outputs of the NAND gates NAND1, NAND2, NAND5, NAND6, NAND9, and NAND10 are high. Accordingly, the outputs A, B, and C of the first to third control units are deactivated to a low level.

When the memory is set as the first test mode, the first test mode signal TCROR is activated to a high level, and the active command ACT is activated to a high level and transmitted as the signal ACTT. Then, the output of the NAND gate NAND1 becomes low the output of the NAND gate NAND3 becomes high, and the output of the NAND gate NAND4 becomes low. Since the first test mode signal TCROR is activated, the output A of the first control unit is activated to a high level when the output of the NAND gate NAND3 becomes high. Since the output A of the first control unit is activated, the clock generation enable signal TCK_EN is activated. Then, when the calibration command ZQC is activated and transmitted as the signal ZQCT, the output of the NAND gate NAND2 becomes low. Accordingly, the output of the NAND gate NAND4 become high, and the output of the NAND gate NAND3 becomes low. Accordingly, the output A of the first control unit is deactivated to a low level. As a result, the clock generation enable signal TCK_EN is deactivated to a low level.

When the memory is set as the second test ode, the second test mode signal TCAWR is activated to a high level, and the write command WR is then activated to a high level and transmitted as the signal WRT. Then, the output of the NAND gate NAND5 becomes low, the output of the NAND gate NAND7 becomes high, and the output of the NAND gate NAND8 becomes low. Since the output B of the second control unit is equal to the output of the NAND gate NAND7, the output B of the second control unit is activated when the output of the NAND gate NAND7 becomes high. Since the output B of the second control unit is activated, the clock generation enable signal TCK_EN is activated. Then, when the test precharge command TPRE is activated, the output of the NAND gate NAND6 becomes low. Therefore, the output of the NAND gate NAND5 becomes high, and the output of the NAND gate NAND7 becomes low. Accordingly, the output B of the second control unit is deactivated to a low level. As a result, the clock generation enable signal TCK_EN is deactivated to a low level.

When the memory is set as the third test mode, the third test mode signal TCABIST is activated to a high level, and the active command ACT is activated to a high level and transmitted as the signal ACTT. Then, the output of the NAND gate NAND9 becomes low, the output of the NAND gate NAND11 becomes high, and the output of the NAND gate NAND12 becomes low. Since the third test mode signal TCADIST is activated, the output C of the third control unit is activated to a high level when the output of the NAND gate NAND11 becomes high. Since the output C of the third control unit is activated, the clock generation enable signal TCK_EN is activated. Then, when the test precharge command TPRE is activated, the output of the NAND gate NAND10 becomes low. Therefore, the output of the NAND gate NAND12 becomes high, and the output of the NAND gate NAND11 becomes low. Accordingly, the output C of the third control unit is deactivated to a low level. As a result, the clock generation enable signal TCK_EN is deactivated to a low level.

FIG. 2 illustrates a case in which the clock generation control unit 133 includes all of the first to third control units 210, 220, and 230. As described with reference to FIG. 1, however, the memory may be designed to support one or more of the first to third test modes. In this case, the clock generation control unit 133 may include only a control unit corresponding to each of the test modes. For example, when the memory supports only the first test mode, the clock generation control unit 133 may include only the first control unit 210, and when the memory supports the second and third test modes, the clock generation control unit 133 may include only the second and third control units 220 and 230.

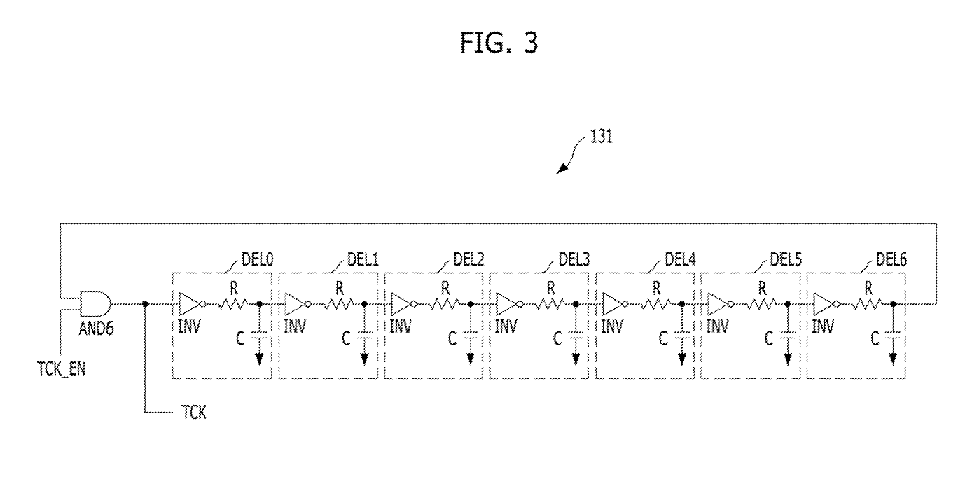

FIG. 3 is a diagram of the test clock generation unit 131 in accordance with the exemplary embodiment of the present invention.

Referring to FIG. 3, the test clock generation unit 131 includes a plurality of unit delays DEL0 to DEL6. Each of the unit delays includes an inverter INV, a resistor R, and a capacitor C. The resistor R and the capacitor C are configured to delay a signal, and the inverter INV is configured to toggle a signal. The test clock generation unit 131 includes an odd number of unit delays DEL0 to DEL6.

When the clock generation enable signal TCK_EN is deactivated, the output of the AND gate AND6 is fixed to a low level. Therefore, the test clock signal TCK is deactivated. When the clock generation enable signal TCK_EN is activated, the output of the AND gate AND6 is decided by another input instead of the clock generation enable signal TCK_EN. Therefore, the test clock generation unit 131 operates as an oscillator to activate the test clock signal TCK.

FIG. 3 illustrates a case in which the test clock generation unit 131 includes seven unit delays, but the number of unit delays may differ depending on design. When the number of unit delays increases, the sum of delay values of the unit delays increases. Therefore, the frequency of the test clock signal TCK decreases. When the number of unit delays decreases, the sum of delay values of the unit delays decreases. Accordingly, the frequency of the test clock signal TCK increases.

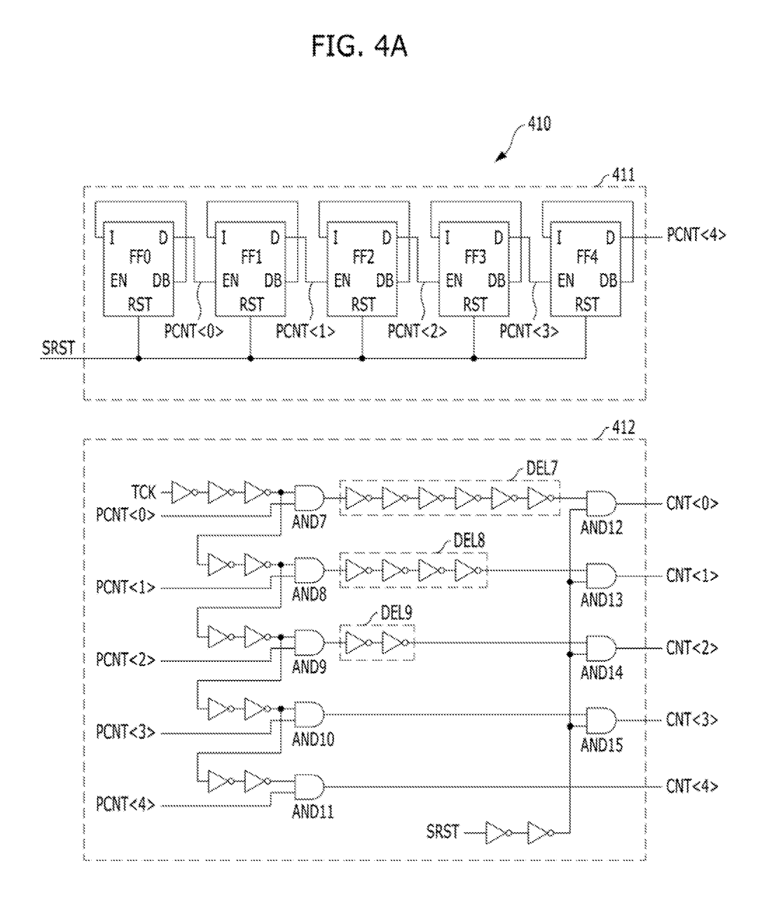

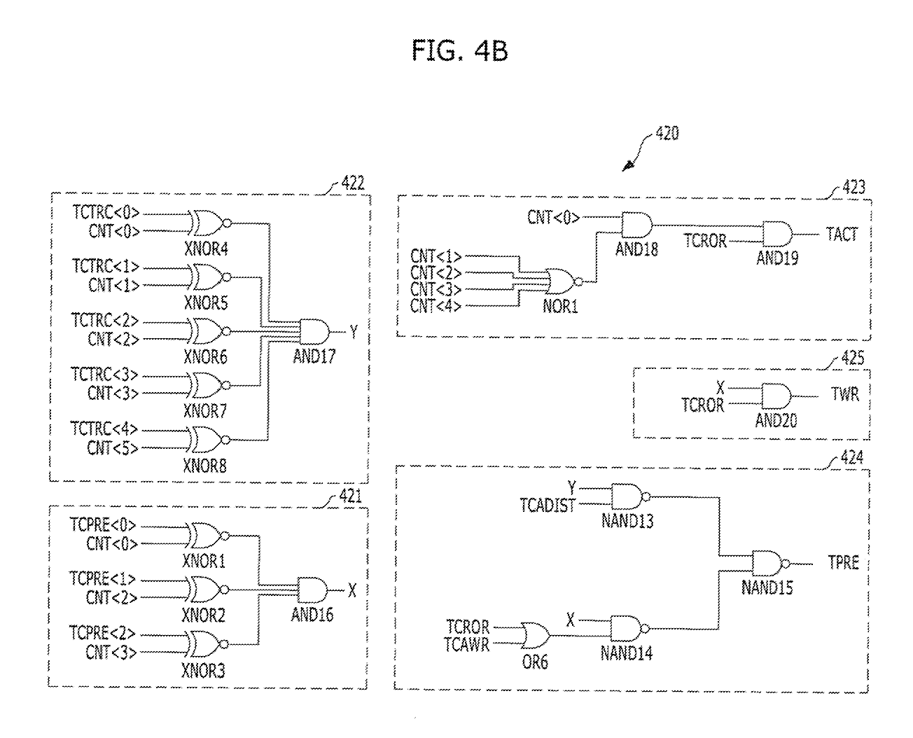

FIGS. 4A and 4B are diagrams of the signal generation unit 132 in accordance with the embodiment of the present invention.

Referring to FIGS. 4A and 4B, the signal generation unit 132 includes a clock counting unit 410 illustrated in FIG. 4A and a counting information determination unit 420 illustrated in FIG. 48. The clock counting unit 410 is configured to count the test clock TCK and generate the counting information CNT<0:4>. The counting information determination unit 420 is configured to activate the test active command TACT when the counting information CNT<0:4> has a predetermined value, activate the test precharge command TPRE when the counting information CNT<0:4> has a value corresponding to one or more pieces of test time information TCPRE<0:2> in a state where the memory is set in the first test mode, activate the test precharge command TPRE when the counting information CNT<0:4> has a value corresponding to one or more pieces of the test time information TCPRE<0:2> in a state where the memory is set in the second test mode, activate the test write command TWR when the counting information CNT<0:4> has a value corresponding to the first test time information TCPRE<0:2> and activate the test precharge command TPRE when the counting information CNT<0:4> has a value corresponding to the second test time information TCTRC<0:4> in a state where the memory is set in the third test mode.

First, referring to FIG. 4A, the operation of the clock counting unit 410 will be described.

The clock counting unit 410 includes a clock counter 411 and an information transmitter 412. The clock counter 411 is configured to count the test clock TCK and generate pre-counting information PCNT<0:4>, and the information transmitter 412 is configured to sort the pre-counting information PCNT<0:4> and transmit the sorted information as the counting information CNT<0:4>.

The clock counter 411 includes a plurality of shifters FF0 to FF4, and outputs of the shifters FF0 to FF4 become the respective bits of the pre-counting information PCNT<0:4>. Each of the shifters FF0 to FF4 includes an input terminal I, an enable terminal EN, an output terminal D, an inverting terminal DB, and a reset terminal RST. The shifter receives a signal inputted to the input terminal I and stores the received signal therein when a signal inputted to the enable terminal EN is activated, and outputs the signal stored therein to the output terminal D when the enable terminal EN is disabled. An inverted signal of the signal stored therein is outputted to the inverting terminal DB. When the signal inputted to the reset terminal RST is activated, the value stored therein is reset (the reset value is high or low). In FIG. 4, it is supposed that the reset value is low. Each of the shifters may include a D-flip flop. A shifter reset signal SRST is inputted to the reset terminal RST. The shifter reset signal SRST may be activated when the operation of activating the test commands TACT, TWR, and TPRE using the counting information CNT<0:4> is completed after the activation period of the test clock signal TCK is ended.

The first shifter FF0 is configured to receive the test clock signal TCK through the enable terminal EN, and each of the other shifters FF1 to FF4 is configured to receive an output of another shifter connected to the previous stage of the shifter through the enable terminal EN. Therefore, the first shifter FF0 is toggled whenever the test clock signal TCK is activated, and each of the other shifters FF1 to FF4 is toggled whenever the output of another shifter connected to the previous stage of the shifter is toggled. Accordingly, since the output of the shifter is toggled one time whenever another shifter connected to the previous stage of the shifter is toggled two times, the pre-counting information PCNT<0:4> has a binary value corresponding to a value obtained by counting the test clock signal TCK. At this time, since the signal passing through the shifter has a predetermined delay value, a difference occurs at a time point when the respective bits of the pre-counting information PCNT<0:4> are updated by toggling of the test clock signal TCK.

The information transmitter 412 is configured to sort the pre-counting information PCNT<0:4> and transmit the sorted information as the counting information CNT<0:4>, in order to remove a skew occurring due to a difference between time points when the respective bits of the pre-counting information PCNT<0:4> are updated. For this operation, the information transmitter 412 includes a plurality of AND gates AND7 to AND15 and a plurality of delays DEL7 to DEL9. When the shifter is a D-flip flop and a signal passes through the D-flip flops, the signal has a delay value corresponding to a delay value of two inverters. Therefore, each of the delays DEL7 to DEL9 has a delay value difference corresponding to the delay value of two inverters. Based on the bit PCNT<4> which is updated latest among the pre-counting information, the bits PCNT<0>, PCNT<1>, PCNT<2>, and PCNT<3> are updated at a time point delayed by a delay value of eight inverters, a delay value of six inverters, a delay value of four inverters, and a delay value of two inverters, respectively, from a time point when the bit PCNT<4> is updated. Therefore, under the supposition that the AND gates AND12 to AND15 have the same delay value as the delay value of two inverters, the delays DEL7 and DEL9 have delay values corresponding to a delay value of six inverter, a delay value of four inverters, and a delay value of two inverters, respectively.

Furthermore, in order to transmit the respective bits of the pre-counting information PCNT<0:4> as the respective bits of the counting information CNT<0:4> during a period in which the test clock TCK is low, signals obtained by delaying an inverted signal of the test clock signal TCK by a delay value of two inverters, a delay value of four inverters, a delay value of six inverters, a delay value of eight inverters, and a delay value of ten inverters are applied to the AND gates AND7 to AND11, respectively. Accordingly, the respective bits of the pre-counting information PCNT<0:4> pass through the corresponding AND gates after being updated while the test clock signal TCK is a low level, and are simultaneously transmitted as the respective bits of the counting information CNT<0:4>. When the shifter reset signal SRST is activated, the pre-counting information PCNT<0:4> is not transmitted as the counting information CNT<0:4>.

For reference, the clock counter 411 illustrated in FIG. 4A is only an example, and any counters capable of counting the activation number of the test clock signal TCK may be used as the clock counter 411.

Next, referring to FIG. 4B, the operation of the counting information determination unit 420 will be described.

The counting information determination unit 420 includes a first comparator 421, a second comparator 422, a first signal generator 423, a second signal generator 424, and a third signal generator 425. The first comparator 421 is configured to compare the first test time information TCPRE<0:2> to some bits CNT<0:2> of the counting information and output the comparison result X. The second comparator 422 is configured to compare the second test time information TCTRC<0:4> to the counting information CNT<0:4> and output the comparison result V. The first signal generator 423 is configured to generate the test active command TACT. The second signal generator 424 is configured to generate the test precharge command TPRE. The third signal generator 425 is configured to generate the test write command TWR.

The first comparator 422 compares the respective bits TCPRE<0> to TCPRE<2> of the first test time information to the respective bits CNT<0> to CNT<2> of the counting information corresponding to the respective bits TCPRE<0> to TCPRE<2> of the first test time information, and activates the output X to a high level when the respective bits TCPRE<0> to TCPRE<2> of the first test time information are equal to the respective bits CNT<0> to CNT<2> of the counting information. For this operation, the first: comparator 421 may include a plurality of exclusive NOR gates XNOR1 to XNOR3 and an AND gate AND16.

The second comparator 422 compares the respective bits TCTRC<0> to TCTRC<4> of the second test time information to the respective bits CNT<0> to CNT<4> of the counting information corresponding to the respective bits TCTRC<0> to TCTRC<4> of the second test time information, and activates the output X to a high level when the respective bits TCTRC<0> to TCTRC<4> of the second test time information are equal to the respective bits CNT<0> to CNT<4> of the counting information. For this operation, the second comparator 422 may include a plurality of exclusive NOR gates XNOR4 to XNOR8 and an AND gate AND17.

The first signal generator 423 activates the test active command TACT when the counting information CNT<0:4> has a specific value in a state in which the first test mode signal TCROR is activated. FIG. 4B illustrates a case in which the test active command TACT is activated when the respective bits CNT<0> CNT<1>, CNT<2>, CNT<3>, and CNT<4> of the counting information CNT<0:4> are (1, 0, 0, 0, 0). For this operation, the first signal generation unit 423 may include a NOR gate NOR1 and a plurality of AND gates AND18 and AND19.

The second signal generator 424 activates the test precharge command TPRE to a high level in response to the result X when the first test mode signal TCROR or the second test mode signal TCAWR is activated. The result X is obtained by comparing the first test time information TCPRE<0:2> to some bits CNT<0:2> of the counting information, the result X is high when the first test time information TCPRE<0:2> and some bits CNT<0:2> of the counting information are equal to each other. Furthermore, the second signal generator 424 activates the test precharge command TPRE to a high level in response to the result when the third test mode signal TCADIST is activated. The result Y is obtained by comparing the second test time information TCTRC<0:4> to the counting information CNT<0:4>, the result Y is high when the second test time information TCTRC<0:4> and the counting information CNT<0:4> are equal to each other. For this operation, the second signal generation unit 414 may include an OR gate OR6 and a plurality of NAND gates NAND13 to NAND15.

The third signal generator 425 activates the test write command TWR in response to the result X when the third test mode signal TCADIST is activated. For this operation, the third signal generation unit 425 may include an AND gate AND20.

FIG. 4B illustrates the counting information determination 420 in a case where the memory supports all of the first to third test modes. As described with reference to FIG. 1, however, the memory may be designed to support one or more of the first to third test modes. In this case, the counting information determination unit 420 may include only components to activate the test commands TACT, TAWR, and TPRE in the test modes supported by the memory. For example, when the memory supports only the first test mode, the counting information determination unit 420 may include the first comparator 421, the first signal generator 423, and the third signal generator 424.

In FIG. 4B, the activation conditions of the test commands TACT, TWR, and TPRE may differ depending on design. For example, the test active command TACT may be designed to be activated when the respective bits CNT<0>, CNT<1>, CNT<2>, CNT<3>, and CNT<4> of the counting information CNT<0:4> have a value different from (1, 0, 0, 0, 0). Furthermore, the test active command TACT may be designed to be activated when the counting information CNT<0:4> has a value corresponding to the test time information TCPRE<0:2> and TCTRC<0:4> instead of a specific value. The test write command TWR or the test precharge command TPRE may be designed in the same manner.

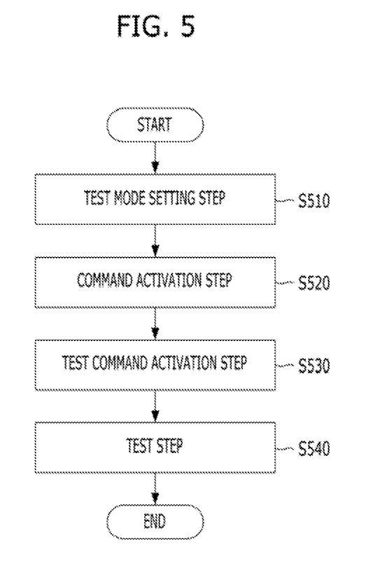

FIG. 5 is a flow chart for explaining a method for testing the memory in accordance with the exemplary embodiment of the present invention.

Referring to FIG. 5, the method for testing the memory includes a test mode setting step S510 of setting the memory in one of the first to third test modes in response to a plurality of address signals ADD<0:A> when a combination of a plurality of command signals CSB, ACTB, RASB, CASB, and WEB corresponds to an MRS command MRS, a command activation step S520 of decoding the plurality of command signals CSB, ACTB, RASB, CASB, and WEB in synchronization with a clock signal CK and activating one or more of a plurality of commands ACT, WR, RD, MRS, and PRE including an active command ACT, a write command WR, and a calibration command ZQC, a test command activation step S530 of activating the test active command TACT for activating a bank BA and the test precharge command TPRE for precharging the bank BA at a time point decided by counting information CNT<0:4> obtained by counting a test clock signal TCK having a higher frequency than the clock signal CK when the memory is set in the first test mode, activating a test precharge command TPRE at a time point that is decided based on the counting information CNT<0:4> after the write command WR is activated when the memory is set in the second test mode, and activating a test write command TWR for writing data into the bank BA and the test precharge command TPRE at a time point that is decided based on the counting information CNT<0:4> when the memory is set in the third test mode, and a test step S540 of activating the bank when a test active command is activated, precharging the bank when the test precharge command is activated, and writing data into the bank when the test write command is activated.

Referring to FIGS. 1 to 5, the method for testing the memory will be described.

At the test mode setting step S510, the command decoder 110 activates the MRS command MRS in response to the plurality of command signals CSB, ACTB, RASB, CASB, and WEB, and sets the operation mode as a test mode. The test mode may be set in the same manner as described with reference to FIG. 1.

When the test mode is set, the command decoder 110 activates one or more of the plurality of commands ACT, WR, RD, MRS, and PRE in response to the plurality of command signals CSB, ACTB, RASB, CASB, and WEB at the command activation step S520.

At the test command activation step S530, when a command is applied, one or more of a plurality of test commands TACT, TWR, and TPRE are activated according to the set test mode. The test commands TACT, TWR, and TPRE may be activated in the same manner as described with reference to FIGS. 1 to 4B.

When the test commands TACT, TWR, and TPRE are activated, an operation of activating the bank BA, an operation of writing data into the bank BA, or an operation of precharging the bank BA is performed in response to pulse signals ACTP, WRP, and PREP in the bank region BAR.

The method for testing the memory in accordance with the embodiment of the present invention may reduce the test time of the memory even though the clock signal inputted from the test device has a low frequency.

Referring to FIGS. 1 to 4B, a memory in accordance with another embodiment of the present invention will be described.

Referring to FIG. 1, the memory includes a bank BA, a command decoder 110, a test decoder 120, and a test controller 130. The bank BA includes a plurality of memory cells. The command decoder 110 is configured to operate in synchronization with a clock signal CK and activate one or more of a plurality of commands ACT, WR, RD, MRS, ZQC, and PRE for the operation of the bank BA in response to a plurality of command signals CSB, ACTB, RASB, CASB, and WEB. The test decoder 120 is configured to set the test mode in response to a plurality of address signals ADD<0:A> when the command MRS for setting a test mode is activated among the plurality of commands ACT, WR, RD, MRS, ZQC, and PRE, and generate test information TCPRE<0:2> and TCTRC<0:4> for a test operation of the bank BA. The test controller 130 is configured to activate one or more of the plurality of test commands TACT, TWR, and TPRE for the test operation of the bank in response to counting information CNT<0:4> obtained by counting the test clock signal TCK having a higher frequency than the clock signal CK and the test information TCPRE<0:2> and TCTRC<0:4> when the memory is set in the test mode.

The operation of the memory is performed in the same manner as described with reference to FIGS. 1 to 4B.

When the memory is set in the test mode by the test decoder 120, it means that the memory is not set in a normal mode, but set in a mode in which one or more of an operation of activating the bank BA, an operation of writing data, and an operation of precharging the bank BA are performed for a test. When the memory is set in the test mode, the command decoder 110 activates one or more of the plurality of commands ACT, WR, RD, MRS, ZQC, and PRE in synchronization with the clock signal CK. However, since the test commands TACT, TWR, and TPRE for actually operating the bank BA in the test mode are activated in synchronization with the test clock signal TCK, the test speed may be reduced.

In accordance with the embodiments of the present invention, the memory operates by internally generating a clock signal having a high frequency even though the test device receives a clock signal having a relatively low frequency and performs a test, thereby reducing the test time.

Furthermore, the memory and the method for testing the same may test various tests of the memory using the clock signal which is internally generated.

Although various embodiments have been described for illustrative purposes, it will be apparent to those skilled in the art that various changes and modifications may be made without departing from the spirit and scope of the invention as defined in the following claims.

What is claimed is:

1. A memory comprising:
a bank comprising a plurality of memory cells;
a command decoder configured to operate in synchronization with a clock signal and activate at least one of a plurality of commands including an active command, a write command, a calibration command, and an MRS command in response to a plurality of command signals;
a test decoder configured to set the memory as a test mode in response to a plurality of address signals and the MRS command; and
a test controller configured to activate at least one internal test command for test operating the bank at a time point that is decided based on counting information obtained by counting a test clock signal having a higher frequency than the clock signal, when the memory is set in the test mode.

2. The memory of claim 1, wherein the at least one internal test command configured to include a test active command for activating the bank, a test precharge command for precharging the bank and a test write command for writing data into the bank.

3. The memory of claim 2, wherein the test decoder generates at least one test time information for deciding a time point when the at least one internal test command are activated.

4. The memory of claim 3, wherein the at least one internal test command configured to include the test active command and the test precharge command,
wherein the test controller comprises:
a test clock generation unit configured to generate the test clock signal;
a signal generation unit configured to alternately activate the test active command and the test precharge command in response to the counting information in a state where the memory is set in the test mode; and
a clock generation control unit configured to enable the test clock generation unit in response to the active command and disable the test clock generation unit in response to the calibration command, in a state where the memory is set in the test mode.

5. The memory of claim wherein the signal generation unit comprises:
a clock counting unit configured to count the test clock signal and generate the counting information; and
a counting information determination unit configured to activate the test active command when the counting information has a predetermined value, and activate the test precharge command when the counting information has a value corresponding to the test time information, in a state where the memory is set in the test mode.

6. The memory of claim 3, wherein the at least one internal test command configured to include the test precharge command,
wherein the test controller configured to activate the test precharge command after the write command is activated.

7. The memory of claim 6, wherein the test controller comprises:
a test clock generation unit configured to generate the test clock signal;
a signal generation unit configured to activate the test precharge command at a time point that is decided based on the counting information and the test time information after the write command is activated in a state where the memory is set in the test mode; and
a clock generation control unit configured to enable the test clock generation unit in response to the write command and disable the test clock generation unit in response to the test precharge command in a state where the memory is set in the test mode.

8. The memory of claim 7, wherein the signal generation unit comprises:
a clock counting unit configured to count the test clock signal and generate the counting information; and
a counting information determination unit configured to activate the test precharge command when the counting information has a value corresponding to the test time information in a state where the memory is set in the test mode.

9. The memory of claim 3, wherein the at least one internal test command configured to include the test write command and the test precharge command,
Wherein the at least one test time information configured to include a first test time information for deciding a time point when the test write command is activated and a second test time information for deciding a time point when the test precharge command is activated.

10. The memory of claim 9, wherein the test controller comprises:
a test clock generation unit configured to generate the test clock signal;
a signal generation unit configured to activate the test write command at a time point that is decided based on the counting information and the first test time information after the active command is activated, and activate the test precharge command at a time point that is decided based on the counting information and the second test time information in a state where the memory is set; and
a clock generation unit configured to enable the test clock generation unit in response to the write command and disable the test clock generation unit in response to the test precharge command in a state where the memory is set in the test mode.

11. The memory of claim 10, wherein the signal generation unit comprises:
a clock counting unit configured to count the test clock signal and generate the counting information; and
a counting information determination unit configured to activate the test write command when the counting information has a value corresponding to the first test time information, and activate the test precharge command when the counting information has a value corresponding to the second test time information in a state where the memory is set in the test mode.

12. The memory of claim 11, wherein data written into the bank in response to the test write command is inputted before the test mode is set, and written into the memory cell decided by a plurality of address signals inputted before the test mode is set.

13. The memory of claim 1, wherein the test clock generation unit comprises an oscillator having a plurality of unit delays, and a period in which the test clock signal is toggled corresponds to the sum of delay values of the unit delays.

14. The memory of claim 1, wherein the plurality of commands comprise a write command, a read command, and a precharge command.

15. The memory of claim 1, wherein the plurality of command signals comprise an active signal, a chip select signal, a row address strobe signal, a column address strobe signal, and a write enable signal.

16. A memory comprising:
a bank comprising a plurality of memory cells;
a command decoder configured to operate in synchronization with a clock signal and activate at least one of a plurality of commands including an active command, a write command, a calibration command, and an MRS command in response to a plurality of command signals;
a test decoder configured to set the memory as one of first to third test modes in response to a plurality of address signals and the MRS command; and
a test controller configured to activate a test active command for activating the bank and a test precharge command for precharging the bank at a time point that is decided based on counting information obtained by counting a test clock signal having a higher frequency than the clock signal when the first test mode is set, activate the test precharge command at a time point that is decided based on the counting information after the write command is activated when the second test mode is set, and activate a test write command for writing data into the bank and the test precharge command at a time point that is decided based on the counting information when the third test mode is set.

17. The memory of claim 16, wherein the test decoder generates a first test time information and a second test time information.

18. The memory of claim 17, wherein the test controller comprises:
a test clock generation unit configured to generate the test clock signal;
a signal generation unit configured to alternately activate the test active command and the test precharge command in response to the counting information in a state where the first test mode is set, activate the test precharge command at a time point that is decided based on the counting information and the first test time information after the write command is activated in a state where the second test mode is set, and activate the test write command at a time point that is decided based on the counting information and the first test time information, and activate the precharge signal at a time point that is decided by the counting information and the second test time information after the active command is activated in a state where the third test mode is set; and
a clock generation control unit configured to enable the test clock generation unit in response to the active command and disable the test clock generation unit in response to the calibration command in a state where the first test mode is set, enable the test clock generation unit in response to the write command and disable the test clock generation unit in response to the test precharge command in a state where the second test mode is set, and enable the test clock generation unit in response to the write command and disable the test clock generation unit in response to the test precharge command in a state where the third test mode is set.

19. The memory of claim 18, wherein the signal generation unit comprises:
a clock counting unit configured to count the test clock signal and generate the counting information; and
a counting information determination unit configured to activate the test active command when the counting information has a predetermined value and activate the test precharge command when the counting information has a value corresponding to the test time information in a state where the first test mode is set, activate the test precharge command when the counting information has a value corresponding to the test time information in a state where the second test mode is set, and activate the test write command when the counting information has a value corresponding to the first test time information and activate the test precharge command when the counting information has a value corresponding to the second test time information in a state where the third test mode is set.

20. The memory of claim 19, wherein when the third test mode is set, data written into the bank in response to the test write command is inputted before the test mode is set, and written into a memory cell decided by a plurality of address signals inputted before the test mode is set.

21. A method for testing a memory which includes a bank having a plurality of memory cells, the method comprising:
setting one of first to third test modes in response to a plurality of address signals when a combination of a plurality of command signals corresponds to an MRS signal;
decoding the plurality of command signals in synchronization with a clock signal and activating at least one of a plurality of commands including an active command, a write command, and a calibration command; and
activating a test active command for activating the bank and a test precharge command for precharging the bank at a time point that is decided based on counting information obtained by counting a test clock signal having a higher frequency than the clock signal when the first test mode is set, activating the test precharge command at a time point that is decided based on the counting information after the write command is activated when the second test mode is set, and activating a test write command for writing data into the bank and the test precharge command at a time point that is decided by the counting information when the third test mode is set.

22. The method of claim 21, further comprising:
activating the bank when the test active command is activated;
precharging the bank when the test precharge command is activated; and
writing data into the bank when the test rite command is activated.

23. A memory comprising:
a bank comprising a plurality of memory cells;
a command decoder configured to operate in synchronization with a clock signal and activate at least one of a plurality of commands for an operation of the memory in response to a plurality of command signals;
a test decoder configured to set the memory as a test mode in response to a plurality of address signals when a command for setting the test mode among the plurality of commands is activated, and generate test information for a test operation of the bank; and
a test controller configured to activate at least one of a plurality of test commands for the test operation of the bank in response to the test information and counting information obtained by counting a test clock signal having a higher frequency than the clock signal when the test mode is set.
